(19) United States
(12) Patent Application Publication
(10) Pub. No.: US 2026/0147434 A1
(43) Pub. Date: May 28, 2026

(54) Electronic Devices Having Moisture-Insensitive Optical Touch Sensors

(71) Applicant: Apple Inc., Cupertino, CA (US)

(72) Inventors: Mohammad Yeke Yazdandoost, Foster City, CA (US); Ting Sun, Cupertino, CA (US)

(21) Appl. No.: 19/446,615

(22) Filed: Jan. 12, 2026

Related U.S. Application Data
(63) Continuation of application No. 18/175,672, filed on Feb. 28, 2023.
(60) Provisional application No. 63/333,045, filed on Apr. 20, 2022.
(60) Provisional application No. 63/356,853, filed on Jun. 29, 2022.

(51) Int. Cl. G06F 3/042

(52) U.S. Cl. CPC G06F 3/0421

(57) ABSTRACT

An electronic device may have a touch sensitive display that is insensitive to the presence of moisture. The display may have a two-dimensional optical touch sensor that gathers touch input while the electronic device is immersed in water or otherwise exposed to moisture. The optical touch sensor may include light sources and light detectors. The light sources and the light sensors may be mounted on a common substrate with an array of image pixels. The image pixels may be formed by crystalline semiconductor light-emitting diode dies. Angular filters may be included over the light sources and/or the light detectors to improve discrimination between a user's finger and water droplets. The angular filters may be on-axis light blocking angular filters or off-axis light blocking angular filters.

This application is a continuation of U.S. non-provisional patent application Ser. No. 18/175,672, filed Feb. 28, 2023, which claims the benefit of U.S. provisional patent application No. 63/356,853, filed Jun. 29, 2022, and U.S. provisional patent application No. 63/333,045, filed Apr. 20, 2022, which are hereby incorporated by reference herein in their entireties.

### FIELD

This relates generally to electronic devices, and, more particularly, to electronic devices with touch sensors.

### BACKGROUND

Electronic devices such as tablet computers, cellular telephones, and other equipment are sometimes provided with touch sensors. For example, displays in electronic devices are often provided with capacitive touch sensors to receive touch input. It can be challenging to operate such sensors in the presence of moisture.

### SUMMARY

An electronic device may have a touch sensitive display that is insensitive to the presence of moisture. The display may have a two-dimensional optical touch sensor such as a direct illumination optical touch sensor or a total internal reflection touch sensor. The optical touch sensor may be used to gather touch input while the electronic device is immersed in water or otherwise exposed to moisture.

An array of pixels in the display may be used to display images. A display cover layer may overlap the array of pixels. One or more light sources may be included to illuminate an external object such as a finger of a user when the object contacts a surface of the display cover layer. This creates scattered light that may be detected by an array of light sensors. The light sources and the light sensors may be mounted on a common substrate with the array of image pixels (which may be formed by crystalline semiconductor light-emitting diode dies).

Angular filters may be included over the light sources and/or the light detectors to improve discrimination between a user's finger and water droplets. The angular filters may be on-axis light blocking angular filters that block light parallel to the surface normal of the display cover layer and pass light at high angles relative to the surface normal of the display cover layer. The angular filters may be off-axis light blocking angular filters that pass light parallel to the surface normal of the display cover layer and block light at high angles relative to the surface normal of the display cover layer.

### BRIEF DESCRIPTION OF THE DRAWINGS

FIG. 1 is a schematic diagram of an illustrative electronic device in accordance with various embodiments.

FIG. 2 is a perspective view of an illustrative electronic device in accordance with various embodiments.

FIG. 3 is a side view of an illustrative electronic device in accordance with various embodiments.

FIG. 4 is a top view of an illustrative array of pixels for an electronic device in accordance with various embodiments.

FIGS. 5 and 6 are side views of illustrative pixel arrays for electronic devices in accordance with various embodiments.

FIG. 7 is a side view of an illustrative optical touch sensor arrangement in accordance with various embodiments.

FIG. 8 is a side view of an illustrative optical touch sensor arrangement based on total internal reflection in accordance with various embodiments.

FIG. 9 is a side view of an illustrative light source configured to emit light into a display cover layer through an index-matching structure in accordance with various embodiments.

FIGS. 10, 11, and 12 are side views of illustrative display and sensor arrangements with different numbers of pixel layers in accordance with various embodiments.

FIG. 13 is a side view of an illustrative off-axis light blocking angular filter for a photodetector in accordance with various embodiments.

FIG. 14 is a side view of an illustrative on-axis light blocking angular filter for a photodetector in accordance with various embodiments.

FIG. 15 is a side view of an illustrative off-axis light blocking angular filter for a light source in accordance with various embodiments.

FIG. 16 is a side view of an illustrative on-axis light blocking angular filter for a light source in accordance with various embodiments.

FIG. 17 is a side view of an illustrative angular filter with a microlens over an aperture in accordance with various embodiments.

FIG. 18 is a side view of an illustrative angular filter with a microlens that is offset relative to an aperture in accordance with various embodiments.

FIG. 19 is a side view of an illustrative angular filter with a single masking layer in accordance with various embodiments.

FIG. 20 is a side view of an illustrative mask layer with an aperture that has a thickness and a smaller width than the thickness in accordance with various embodiments.

FIG. 21 is a side view of an illustrative optical touch sensor with light sources that are not covered by angular filters and with photodetectors that are covered by on-axis light blocking angular filters in accordance with various embodiments.

FIG. 22 is a side view of an illustrative optical touch sensor with light sources that are covered by off-axis light blocking angular filters and with photodetectors that are covered by on-axis light blocking angular filters in accordance with various embodiments.

FIG. 23 is a side view of an illustrative optical touch sensor with light sources that are not covered by angular filters and with photodetectors that are not covered by angular filters in accordance with various embodiments.

FIG. 24 is a side view of an illustrative optical touch sensor with light sources that are not covered by angular filters and with photodetectors that are covered by off-axis light blocking angular filters in accordance with various embodiments.

FIG. 25 is a side view of an illustrative optical touch sensor with light sources that are covered by on-axis light blocking angular filters and with photodetectors that are covered by off-axis light blocking angular filters in accordance with various embodiments.

FIG. 26 is a schematic diagram of an illustrative optical touch sensor in accordance with various embodiments.

### DETAILED DESCRIPTION

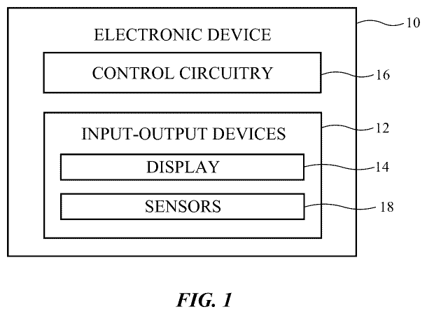

A schematic diagram of an illustrative electronic device that may include an optical touch sensor is shown in FIG. 1. Electronic device 10 of FIG. 1 may be a computing device such as a laptop computer, a computer monitor containing an embedded computer, a tablet computer, a cellular telephone, a media player, or other handheld or portable electronic device, a smaller device such as a wristwatch or other device worn on a user's wrist, a pendant device, a headphone or earpiece device, a head-mounted device such as eyeglasses, goggles, or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, equipment that implements the functionality of two or more of these devices, or other electronic equipment. Illustrative configurations in which device 10 is a portable device such as a wristwatch, cellular telephone, or tablet computer and, more particularly, a portable device that is water resistant or waterproof may sometimes be described herein as an example.

As shown in FIG. 1, electronic device 10 may have control circuitry 16. Control circuitry 16 may include storage and processing circuitry for supporting the operation of device 10. The storage and processing circuitry may include storage such as hard disk drive storage, nonvolatile memory (e.g., flash memory or other electrically-programmable-read-only memory configured to form a solid state drive), volatile memory (e.g., static or dynamic random-access-memory), etc. Processing circuitry in control circuitry 16 may be used to control the operation of device 10. The processing circuitry may be based on one or more microprocessors, microcontrollers, digital signal processors, baseband processors, power management units, audio chips, application specific integrated circuits, etc. Control circuitry 16 may include communications circuitry for supporting wired and/or wireless communications between device 10 and external equipment. For example, control circuitry 16 may include wireless communications circuitry such as cellular telephone communications circuitry and wireless local area network communications circuitry.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, haptic output devices, cameras, light-emitting diodes and other status indicators, data ports, etc. A user can control the operation of device 10 by supplying commands through input-output devices 12 and may receive status information and other output from device 10 using the output resources of input-output devices 12.

Input-output devices 12 may include one or more displays such as display 14. Display 14 may be an organic light-emitting diode display, a display formed from an array of crystalline semiconductor light-emitting diode dies, a liquid crystal display, or other display. Display 14 may be a touch screen display that includes an optical touch sensor for gathering touch input from a user. The optical touch sensor may be configured to operate even when device 10 is immersed in water or otherwise exposed to moisture. If desired, the optical touch sensor may also be configured to operate when a user is wearing gloves, which might be difficult or impossible with some capacitive touch sensors. Moreover, because the optical touch sensor operates optically, the touch sensor is not impacted by grounding effects that might impact the operation of capacitive touch sensors.

As shown in FIG. 1, input-output devices 12 may include sensors 18. Sensors 18 may include touch sensors. Touch sensors may be provided for display 14 and/or other portions of device 10 and may be formed from an array of capacitive touch sensor electrodes, acoustic touch sensor structures, resistive touch components, force-based touch sensor structures, light-based touch sensor structures, or other suitable touch sensor arrangements. Illustrative optical touch sensor arrangements for device 10 (e.g., for display 14 of device 10) are sometimes described herein as an example.

Sensors 18 may include capacitive sensors, light-based proximity sensors, magnetic sensors, accelerometers, force sensors, touch sensors, temperature sensors, pressure sensors, inertial measurement units, accelerometers, gyroscopes, compasses, microphones, radio-frequency sensors, three-dimensional image sensors (e.g., structured light sensors with light emitters such as infrared light emitters configured to emit structured light and corresponding infrared image sensors, three-dimensional sensors based on pairs of two-dimensional image sensors, etc.), cameras (e.g., visible light cameras and/or infrared light cameras), light-based position sensors (e.g., lidar sensors), monochrome and/or color ambient light sensors, and other sensors. Sensors 18 such as ambient light sensors, image sensors, optical proximity sensors, lidar sensors, optical touch sensors, and other sensors that use light and/or components that emit light such as status indicator lights and other light-emitting components may sometimes be referred to as optical components.

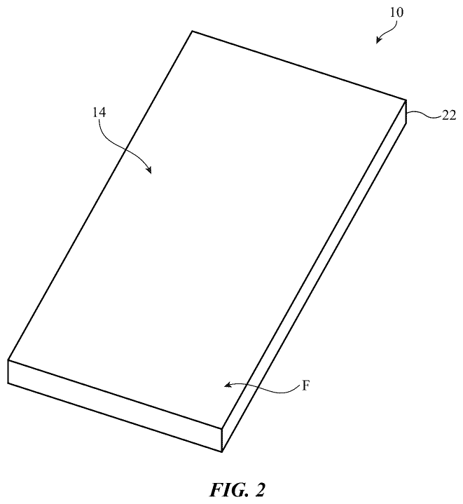

A perspective view of an illustrative electronic device of the type that may include an optical touch sensor is shown in FIG. 2. In the example of FIG. 2, device 10 includes a display such as display 14 mounted in housing 22. Display 14 may be a liquid crystal display, a light-emitting diode display such as an organic light-emitting diode display or a display formed from crystalline semiconductor light-emitting diode dies, or other suitable display. Display 14 may have an array of image pixels extending across some or all of front face F of device 10 and/or other external device surfaces. The array of image pixels may be rectangular or may have other suitable shapes. Display 14 may be protected using a display cover layer (e.g., a transparent front housing layer) such as a layer of transparent glass, clear plastic, sapphire, or other clear layer. The display cover layer may overlap the array of image pixels.

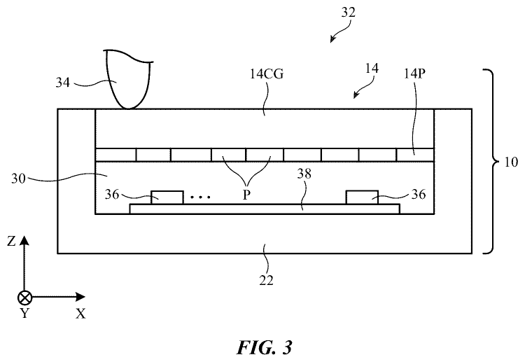

Housing 22, which may sometimes be referred to as an enclosure or case, may be formed of plastic, glass, ceramics, fiber composites, metal (e.g., stainless steel, aluminum, etc.), other suitable materials, or a combination of any two or more of these materials. As shown in the side view of device 10 of FIG. 3, housing 22 and display 14 may separate an interior region of device 10 such as interior region 30 from an exterior region surrounding device 10 such as exterior region 32. Housing 22 may be formed using a unibody configuration in which some or all of housing 22 is machined or molded as a single structure or may be formed using multiple structures (e.g., an internal frame structure, one or more structures that form exterior housing surfaces, etc.). If desired, a strap may be coupled to a main portion of housing 22 (e.g., in configurations in which device 10 is a wristwatch or head-mounted device). Internal electrical components 36 (e.g., integrated circuits, discrete components, etc.) for forming control circuitry 16 and input-output devices 12 may be mounted in interior 30 of housing 22 (e.g., on one or more substrates such as printed circuit 38). In some configurations, components 36 may be attached to display 14 (e.g., circuitry may be mounted to the surface of display 14). To obtain touch input from a user's fingers or other external object (see, e.g., user finger 34), display 14 may include a touch sensor such as an optical touch sensor (e.g., a two-dimensional optical touch sensor that gathers information on the XY location of a user's finger or other external object when that object touches the surface of display 14).

Display 14 may include a display panel such as display panel 14P that contains pixels P covered by display cover layer 14CG. The pixels of display 14 may cover all of the front face of device 10 or display 14 may have pixel-free areas (e.g., notches, rectangular islands, inactive border regions, or other regions) that do not contain any pixels. Pixel-free areas may be used to accommodate an opening for a speaker and windows for optical components such as image sensors, an ambient light sensor, an optical proximity sensor, a three-dimensional image sensor such as a structured light three-dimensional image sensor, a camera flash, an illuminator for an infrared image sensor, an illuminator for a three-dimensional sensor such as a structured light sensor, a time-of-flight sensor, a lidar sensor, etc.

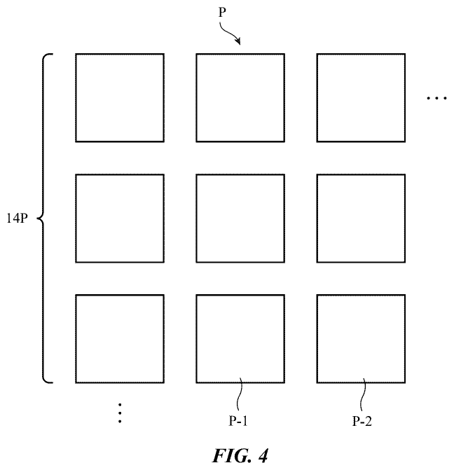

FIG. 4 is a top view of an array of illustrative pixels P in display panel (display) 14P. As shown in FIG. 4, pixels P may include image pixels such as pixel P-1 that are used in presenting images for a user of device 10. Image pixels in display 14 may, for example, include a rectangular array of red, green, and blue light-emitting diodes or backlit red, green, and blue liquid crystal display pixels for presenting color images to a user.

Pixels P may also contain optical touch sensor pixels such as pixel P-2. Optical touch sensor pixels may include pixels that serve as light detectors and/or light emitters. Emitted light that reflects from a user's finger on the surface of display 14 may be detected using the light detectors, thereby determining the location of the user's finger. If desired, diodes or other components may be used to form pixels that can be operated both as image pixels and as touch sensor pixels. When used as touch sensor pixels, image pixels can be configured to emit optical touch sensor illumination and/or to detect optical touch sensor light. For example, a display emitter can be used to produce image light for a display while also being used to produce optical touch sensor illumination, and/or while also being used to serve as a photodetector (sometimes referred to as a light detector) for an optical touch sensor.

Image pixels such as pixels P-1 and/or optical touch sensor pixels P-2 may have any suitable pitch. For example, image pixels may have a density that is sufficient to display high-quality images for a user (e.g., 200-300 pixels per inch or more, as an example), whereas optical touch sensor pixels may, if desired, have a lower density (e.g., less than 200 pixels per inch, less than 50 pixels per inch, less than 20 pixels per inch, etc.). Optical touch sensor pixels P-2 may include both light sources and light detectors. The light sources may have a density of less than 200 pixels per inch, less than 50 pixels per inch, less than 20 pixels per inch, etc. The light detectors may have a density of less than 200 pixels per inch, less than 50 pixels per inch, less than 20 pixels per inch, etc.

Image pixels emit visible light for viewing by a user. For example, in a color display, image pixels may emit light of different colors of image light such as red, green, and blue light, thereby allowing display 14 to present color images. Optical touch sensor pixels may emit and/or detect visible light and/or infrared light (and/or, if desired, ultraviolet light).

In some configurations, optical touch sensor light for illuminating a user's fingers passes directly through the thickness of display cover layer 14CG from its interior surface to its exterior surface. Optical touch sensors in which light that illuminates the user's fingers passes outwardly from light sources such as light-emitting pixels in display panel 14P directly through the thickness of display cover layer 14CG before being backscattered in the reverse (inward) direction to the light detectors of the optical touch sensors may sometimes be referred to herein as direct illumination optical touch sensors.

In other configurations, light for an optical touch sensor may be guided within layer 14CG in accordance with the principal of total internal reflection. For example, a light-emitting diode may emit light into the righthand edge of display cover layer 14CG that is guided from the righthand edge of display cover layer 14CG to the opposing lefthand edge of display cover layer 14CG within the light guide formed by display cover layer 14CG. In this way, light may be guided laterally across layer 14CG in the absence of contact from a user's finger. When a user's finger touches the surface of layer 14CG, total internal reflection can be locally defeated. This local frustration of total internal reflection scatters light inwardly toward the light detectors of the optical touch sensor. Optical touch sensors that are based on locally defeating total internal reflection may sometimes be referred to herein as total internal reflection optical touch sensors. If desired, objects other than the fingers of users (e.g., a computer stylus, a glove, and/or other external objects with appropriate optical properties) may also locally defeat total internal reflection, thereby allowing the optical touch sensors to function over a wide range of operating environments.

Pixels P that emit light and pixels P that detect light in display panel 14P may be formed using shared structures and/or structures that are separate from each other. These structures may be located in the same plane (e.g., as part of a single layer of pixels on a single substrate) and/or may include components located in multiple planes (e.g., in arrangements in which some components are formed in a given layer and other components are formed in one or more additional layers above and/or below the given layer).

Consider, as an example, an optical touch sensor that contains an array of photodetectors formed from reverse-biased diodes. These diodes may be dedicated photodetectors or may be light-emitting didoes that serve as light detectors when reverse biased and that serve as light sources when forward biased. Light sources in the optical touch sensor may include visible light sources (e.g., visible light sources dedicated to use in the optical touch sensor or visible light sources that also serve as image pixels) and/or may include infrared light sources. Light-emitting pixels for the optical touch sensor may be formed from light-emitting diodes (e.g., dedicated light-emitting diodes or diodes that serve as light-emitting diodes when forward biased and that serve as photodetectors when reversed biased). Light-emitting pixels may also be formed from pixels P that are backlit with light from a backlight unit to form backlit pixels (e.g., backlit liquid crystal display pixels). In general, any type of photodetector signal processing circuitry may be used to detect when a photodetector has received light. For example, photodetectors may be configured to operate in a photoresistor mode in which the photodetectors change resistance upon exposure to light and corresponding photodetector signal processing circuitry may be used to measure the changes in photodetector resistance. As another example, the photodetectors may be configured to operate in a photovoltaic mode in which a voltage is produced when light is sensed and corresponding photodetector signal processing circuitry may be used to detect the voltage signals that are output from the photodetectors. Semiconductor photodetectors may be implemented using phototransistors or photodiodes. Other types of photosensitive components may be used, if desired.

FIG. 5 is a side view of an illustrative display having an array of pixels P that are not backlit. Pixels P of FIG. 5 may include light-emitting diodes (e.g., organic light-emitting diodes such as thin-film organic light-emitting diodes and/or light-emitting diodes formed from crystalline semiconductor light-emitting diode dies). During operation, image pixels formed from the light-emitting diodes may present an image on display 14 that is visible to a user such as viewer 40 who is viewing display 14 in direction 42.

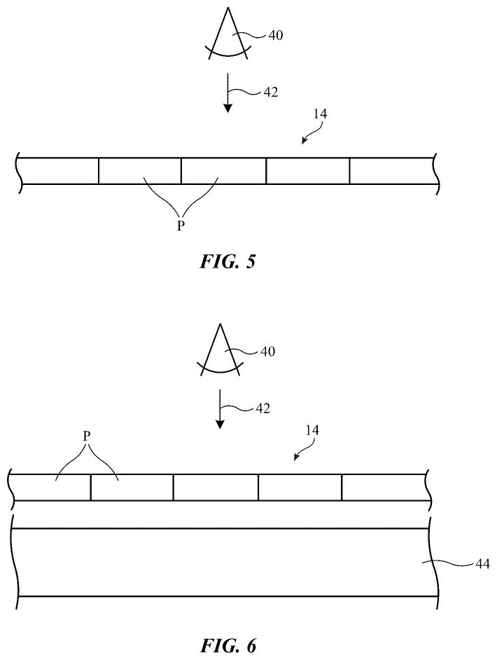

FIG. 6 is a side view of an illustrative display having an array of pixels P that are backlit using backlight unit 44. Backlight unit 44 may include one or more strips of light-emitting diodes that emit light into a backlight unit light guide layer (e.g., a clear optical film with light-scattering structures). As the emitted light propagates through the light guide layer, the scattered light serve as backlight illumination for pixels P (e.g., liquid crystal display pixels). In another illustrative configuration, backlight unit 44 is a direct lit backlight unit that contains an array of backlight light-emitting diodes that provide backlight (e.g., an array-type backlight unit that supports local dimming functionality).

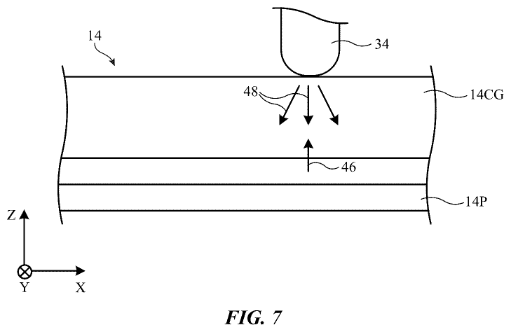

FIG. 7 is a side view of an illustrative display with a direct illumination optical touch sensor. As shown in FIG. 7, visible and/or infrared light sources associated with display panel 14P may emit illumination 46 that travels directly through display cover layer 14CG from its inner surface to its outer surface, thereby illuminating an external object contacting the surface of display 14 such as finger 34. This creates localized backscattered light 48 that propagates in the inward (−Z) direction and that is detected by photodetectors associated with display panel 14P that are directly below finger 34. In this way, the optical touch sensor can determine the lateral position (XY location) of finger 34.

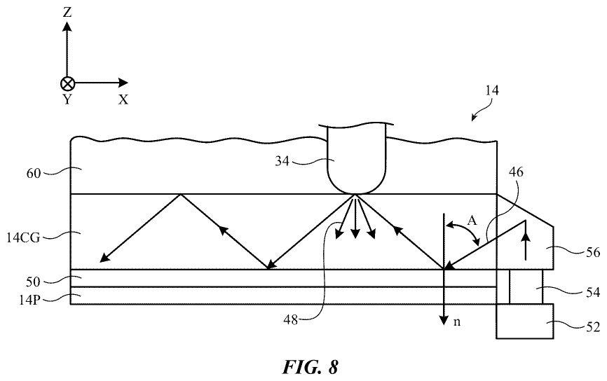

FIG. 8 is a side view of an illustrative display with a total internal reflection optical touch sensor. As shown in FIG. 8, display 14 may include display cover layer 14CG and display panel 14P. Image pixels in panel 14P may display images that are viewable by a viewer through display cover layer 14CG. The outermost surface of display panel 14P may be separated from the opposing innermost surface of display cover layer 14CG by layer 50. Layer 50 may be formed from air, liquid, polymer (e.g., polymer adhesive such as optically clear adhesive, pressure sensitive adhesive, other polymer materials, etc.), glass, other materials, and/or combinations of these materials. Light 46 maybe coupled into layer 14CG through the sidewalls of layer 14CG (e.g., at the righthand edge surface at the peripheral of display cover layer 14CG in the example of FIG. 8).

Any suitable optical coupling structures may be used to direct light 46 into display cover layer 14CG. In the example of FIG. 8, light 46 is emitted by a light source such as light source 52. Light source 52 may be a light-emitting diode such as a visible or infrared light-emitting diode or a visible or infrared laser diode. Collimator 54 may be used to collimate the emitted light from light source 52 (e.g., to form a beam of light with parallel light rays). A prism such as prism 56 or other optical coupler may be coupled between collimator 54 and display cover layer 14CG. Prism 56 may, for example, be mounted to the edge of display cover layer 14CG to help direct light into the edge of display cover layer 14CG. During operation, optical coupling structures such as collimator 54 and a prism or other optical coupler may be used to couple light 46 that is emitted from light source 52 into the interior of display cover layer 14CG in a beam that is oriented at a desired angle relative to the surfaces of layer 14CG (e.g., at an angle A with respect to surface normal n of display cover layer 14CG). At this angle A, light 46 will propagate within layer 14CG in accordance with the principal of total internal reflection unless total internal reflection is locally defeated by the presence of finger 34 on the outer surface of layer 14CG.

Angle A is selected (and the materials used for layer 14CG and layer 50 are selected) so that light 46 will reflect from the innermost surface of layer 14CG in accordance with the principal of total internal reflection. Layer 14CG may, as an example, have a refractive index n1 (e.g., 1.5 for glass or 1.76 for sapphire as examples), whereas layer 50 may have a refractive index n2 that is less than n1 (e.g., less than 1.5 when layer 14CG is glass or less than 1.76 when layer 14CG is sapphire). The refractive index difference between n1 and n2 may be at least 0.05, at least 0.1, at least 0.2, or other suitable value).

Angle A is also selected so that light 46 will reflect from the uppermost surface of layer 14CG in accordance with the principal of total internal reflection (in the absence of finger 34). In some environments, device 10 will be immersed in water 60 or otherwise exposed to moisture (rain droplets, perspiration, fresh or salt water surrounding device 10 when a user is swimming, etc.). Angle A is preferably selected to ensure that the presence of water 60 will not defeat total internal reflection while ensuring that the presence of finger 34 will locally defeat total internal reflection and thereby produce localized scattered light 48 for detection by the nearby photodetectors of the optical touch sensor. This allows the total internal reflection optical touch sensor to operate whether or not the some or all of the surface of display 14 is immersed in water or otherwise exposed to moisture.

Consider, as an example, a first illustrative scenario in which layer 14CG is formed from a material with a refractive index of 1.5 (e.g., glass). Finger 34 may be characterized by a refractive index of 1.55. Water 60 may be characterized by a refractive index of 1.33. Layer 50 may have a refractive index of less than 1.5. In this first scenario, total internal reflection at the upper surface of layer 14CG when water 60 is present is ensured by the selection of a material for layer 14CG with a refractive index greater than water and by selecting angle A to be greater than the critical angle at the upper surface of layer 14CG (in this example, greater than 62.46°, which is the critical angle associated with total internal reflection at the glass/water interface). To ensure total internal reflection is sustained at the lower surface of layer 14CG, the selected value of A should be greater than the critical angle associated with the lower interface. If, as an example, layer 50 is formed from a material with a refractive index of 1.33 (the same as water) or less, the critical angle associated with the lower interface will be at least 62.46°, so A should be greater than 62.46°. If, on the other hand, layer 50 is formed from a material with a refractive index between 1.33 and 1.5, the critical angle at the lower interface will be increased accordingly and the angle A should be increased to be sufficient to ensure total internal reflection at the lower interface. Regardless of which value is selected for angle A, total internal reflection will be supported at both the lower and upper surfaces of layer 14CG (whether layer 14CG is in air or immersed in water), so long as finger 34 is not present. Because finger 34 has a refractive index (1.55) that is greater than that of layer 14CG (which is 1.5 in this first scenario), whenever finger 34 is present on the upper surface of layer 14CG, total internal reflection will be defeated at finger 34, resulting in scattered light 48 that can be detected by the light detectors of the total internal reflection optical touch sensor associated with display 14.

The refractive index of layer 14CG need not be less than the refractive index of finger 34. Consider, as an example, a second illustrative scenario in which layer 14CG is formed from a crystalline material such as sapphire with a refractive index of 1.76. In this second scenario, the angle A should be selected to be both: 1) sufficiently high to ensure that total internal reflection is sustained at the upper (and lower) surfaces of layer 14CG in the absence of finger 34 (even if water 60 is present) and 2) sufficiently low to ensure that total internal reflection at the upper surface will be locally defeated when finger 34 is touching the upper surface to provide touch input. Total internal reflection at the upper surface may be ensured by selecting a value of A that is greater than the critical angle associated with a sapphire/water interface (e.g., the value of angle A should be greater than arcsin(1.33/1.76), which is 49.08°). Total internal reflection at the lower interface is ensured by selecting a material for layer 50 that has an index of refraction of 1.33 or less (in which case A may still be greater than 49.08°) or by selecting a material for layer 50 that has a larger index (but still less than 1.55) and adjusting the value of A upwards accordingly. To ensure that total internal reflection at the upper surface can be defeated locally by finger 34, the value of angle A should be less than the critical angle associated with a sapphire/finger interface (e.g., less than arcsin(1.55/1.76), which is 61.72°). Thus, in scenarios in which the refractive index of layer 14CG is greater than the refractive index of finger 34, there will be a range of acceptable values for A bounded by a lower limit (e.g., 49.08° in this example) and an upper limit (e.g., 61.72° in this example).

The example of finger 34 being characterized by a refractive index of 1.55 is merely illustrative. In general, the optical characteristics of finger 34 may be based on a selected optical model for the finger. As one additional example, the finger may be modeled as a two-layer structure with one layer (the epidermis) having a first thickness (e.g., 0.3 millimeters) and a first refractive index (e.g., 1.44) and one layer (the dermis) having a second thickness (e.g., 5 millimeters) and a second refractive index (1.40). These examples are merely illustrative, and the optical model for the finger may be tuned in any desired manner.

Additional details regarding the critical angles associated with water-glass interfaces and air-glass interfaces as well as tuning angular filters based on these critical angles are found in U.S. provisional patent application No. 63/480,465, which is hereby incorporated by reference herein in its entirety.

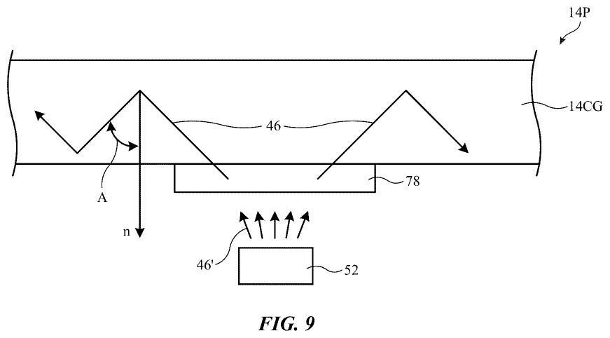

If desired, light 46 may be coupled into layer 14CG for total internal reflection using one or more overlapped light sources 52 (e.g., an array of infrared and/or visible light sources such as light-emitting diodes and/or laser diodes that lie below an array of image pixels in panel 14P). As shown in FIG. 9, for example, display panel 14P may have one or more light sources 52 that emit light 46′ in a vertically oriented cone. Index-matching structures such as layer 78 may be provided with a refractive index value equal to or close to that of layer 14CG to help couple emitted light from each source 52 into layer 14CG and/or may include gratings or other optical coupling structures. The lowermost surface of layer 78 may, if desired, be angled with respect to surface normal n of layer 14CG (e.g., to form a prism) and/or may contact source 52 to help receive light 46′ from source 52 without undesired reflections. The light from source 52 is characterized by rays of light 46 in layer 14CG that are oriented at a desired angle A with respect to surface normal n to support total internal reflection in layer 14CG in the absence of finger 34.

Light sources such as light source 52 of FIG. 9 may be pixels P that are located in, above, and/or below image pixels in panel 14P. If desired, light sources such as light source 52 of FIG. 9 may be formed from multiple light sources (e.g., light sources stacked on top of each other or mounted side-by-side on a shared substrate). In this type of arrangement, each of the multiple light sources may be optimized for a particular function. for example, one light source may be configured to produce display illumination and another may be configured to produce collimated total internal reflection illumination for the optical touch sensor.

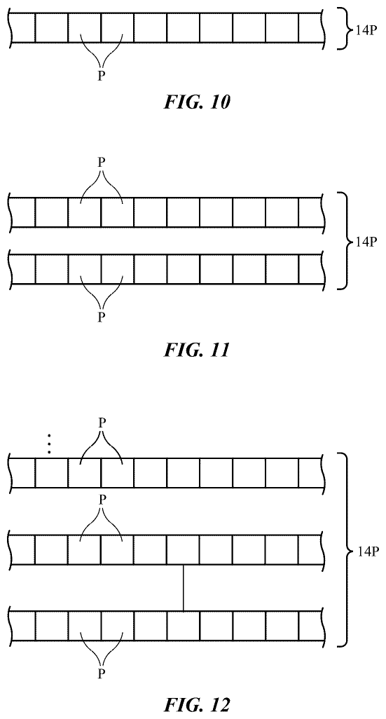

In display 14 (e.g., in display panel 14P), the image pixels that are used in displaying images for a user (e.g., the red, blue, and green pixels in a color display) and/or the optical touch sensor pixels (e.g., light emitters and/or detectors for implementing a direct illumination and/or total internal reflection optical touch sensor) may be implemented using one or more layers of pixels, as shown in the side view of the illustrative displays of FIGS. 10, 11, and 12. FIG. 10 is an illustrative arrangement for display panel 14P that has a single layer of pixels P. In FIG. 11, two layers of pixels P are used in display panel 14P. The diagram of FIG. 12 shows how display panel 14P may, if desired, have three or more layers of pixels P. In general, optical touch sensor pixels may be located in the same layer as image pixels (i.e., coplanar with the image pixels) and/or may be located in a layer that is above or below the image pixels.

Pixels P of FIGS. 10, 11, and 12 may include image pixels and/or optical touch sensor pixels. In some arrangements, pixels P may include backlight pixels that supply backlight illumination in a local dimming backlight unit. The pixels P in different layers may have the same pitch or different pitches. As an example, there may be more image pixels per inch than optical touch sensor pixels. Thin-film structures and/or discrete devices may be used in forming pixels P. In some embodiments of display panel 14P (e.g., displays with a total internal reflection optical touch sensor), light sources for the optical touch sensor may be configured to provide edge illumination (see, e.g., light source 52 of FIG. 8) in addition to or instead of using light sources in pixels P.

It may be desirable to restrict the acceptance angles associated with a given light-detecting pixel. For example, it may be desirable to provide photodetector pixels in an optical touch sensor with angular filters that cause the photodetector pixels to be primarily or exclusively responsive to scattered light rays that are perpendicular to the surface normal n of layer 14CG (e.g., light rays that are traveling directly inward from layer 14CG after scattering from a user's finger 34). Alternatively, it may be desirable to provide photodetector pixels in an optical touch sensor with angular filters that cause the photodetector pixels to be primarily or exclusively responsive to scattered light rays that are at high angles relative to the surface normal n of layer 14CG. Similarly, it may be desirable to provide light sources in an optical touch sensor with angular filters that restrict the emitted light to certain ranges of angles. Applying angular filters to the photodetectors and/or the light sources in an optical touch sensor may help discriminate between water (e.g., water droplets) and a user's finger during operation of the optical touch sensor.

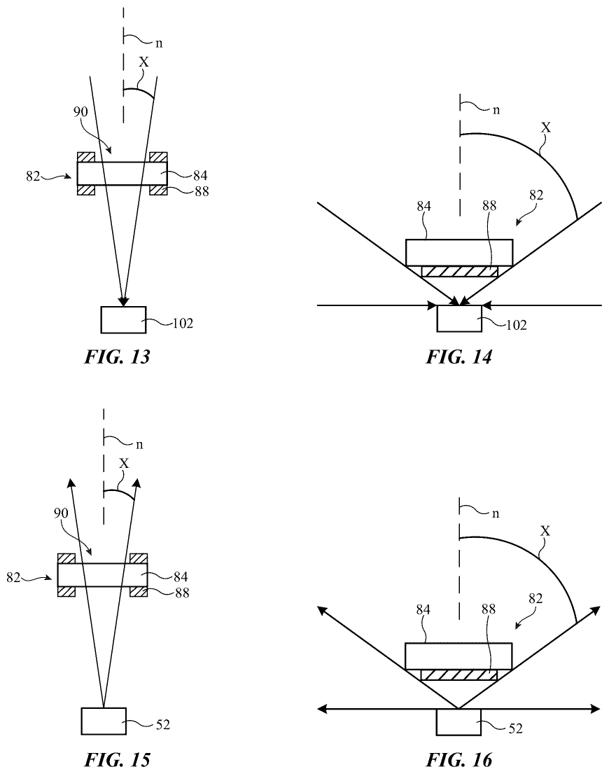

FIG. 13 is a side view of a photodetector with an angular filter. As shown, angular filter 82 is formed over photodetector 102 (sometimes referred to as light detector 102). Angular filter 82 may be formed from one or more mask layers 88 on a transparent layer 84. Mask 88 may be formed from black ink, metal, or other opaque masking materials. Opening 90 may be a circular aperture or other gap in the opaque layer of mask 88. Transparent layer 84 may be one of the layers in panel 14P such as an encapsulation layer or other clear dielectric layer.

As shown in FIG. 13, angular filter 82 blocks light at off-axis angles (e.g., with high angles relative to the surface normal of the display cover layer 14CG) from reaching photodetector 102. Light at on-axis angles (close to the surface normal of the display cover layer 14CG) passes through the angular filter and is detected by photodetector 102. The angular filter in FIG. 13 may therefore sometimes be referred to as an off-axis light blocking filter (because the filter blocks off-axis light). The off-axis light blocking filter may have an acceptance range of angles with boundaries defined by an angle X relative to the surface normal n. The acceptance range of the angular filter in FIG. 13 is between −X degrees and positive X degrees (where X is between 0 and 90 degrees). The angular filter may be designed (e.g., by changing the size of opening 90, the distance between the angular filter and the photodetector, etc.) to have any desired value for X. X may be less than 45 degrees, less than 30 degrees, less than 20 degrees, less than 15 degrees, less than 10 degrees, less than 5 degrees, greater than 45 degrees, greater than 30 degrees, greater than 20 degrees, greater than 15 degrees, greater than 10 degrees, greater than 5 degrees, between 5 degrees and 15 degrees, etc.

The example in FIG. 13 of angular filter 82 blocking off-axis light is merely illustrative. In another possible arrangement, shown in FIG. 14, angular filter 82 may be an on-axis light blocking filter that blocks on-axis light while passing off-axis light. Similar to as in FIG. 13, angular filter 82 in FIG. 14 may be formed from one or more mask layers 88 on a transparent layer 84. Transparent layer 84 may be one of the layers in panel 14P such as an encapsulation layer or other clear dielectric layer. Mask 88 may be formed from black ink, metal, or other opaque masking materials. In FIG. 14, however, mask 88 is centered over photodetector 102. Accordingly angular filter 82 in FIG. 14 blocks light at on-axis angles from reaching photodetector 102. Light at off-axis angles passes through the angular filter and is detected by photodetector 102.

The on-axis light blocking filter may have an acceptance range of angles with boundaries defined by an angle X relative to the surface normal n. The on-axis light blocking filter accepts two discrete cones of light. The acceptance range of the angular filter in FIG. 14 is between −90 degrees and −X degrees and between X degrees and positive 90 degrees (where X is between 0 and 90 degrees). The angular filter may be designed (e.g., by changing the width of mask 88, the distance between the angular filter and the photodetector, etc.) to have any desired value for X. X may be less than 80 degrees, less than 70 degrees, less than 60 degrees, less than 45 degrees, less than 25 degrees, greater than 80 degrees, greater than 70 degrees, greater than 60 degrees, greater than 45 degrees, greater than 25 degrees, between 50 degrees and 70 degrees, etc.

As shown in FIG. 15, an off-axis light blocking angular filter 82 (similar to as shown in FIG. 13) may be positioned over light source 52. The angular filter 82 therefore passes on-axis light from light source 52 while blocking off-axis light from light source 52. The viewing angle of light emitted through the off-axis filter by light source 52 may have a range of angles with boundaries defined by an angle X relative to the surface normal n. The viewing angle of the light source with the off-axis light blocking angular filter in FIG. 15 is between-X degrees and positive X degrees (where X is between 0 and 90 degrees). The angular filter may be designed (e.g., by changing the size of opening 90, the distance between the angular filter and the light source, etc.) to have any desired value for X. X may be less than 45 degrees, less than 30 degrees, less than 20 degrees, less than 15 degrees, less than 10 degrees, less than 5 degrees, greater than 45 degrees, greater than 30 degrees, greater than 20 degrees, greater than 15 degrees, greater than 10 degrees, greater than 5 degrees, between 5 degrees and 15 degrees, etc.

As shown in FIG. 16, an on-axis light blocking angular filter 82 (similar to as shown in FIG. 14) may be positioned over light source 52. The angular filter 82 therefore passes off-axis light from light source 52 while blocking on-axis light from light source 52. The viewing angle of light emitted through the on-axis light blocking filter by light source 52 may have a range of angles with boundaries defined by an angle X relative to the surface normal n. The on-axis light blocking filter passes two discrete cones of light. The viewing angle of the light source with the on-axis light blocking angular filter in FIG. 15 is between −90 degrees and −X degrees and between X degrees and positive 90 degrees (where X is between 0 and 90 degrees). The angular filter may be designed (e.g., by changing the size of opening 90, the distance between the angular filter and the light source, etc.) to have any desired value for X. X may be less than 80 degrees, less than 70 degrees, less than 60 degrees, less than 45 degrees, less than 25 degrees, greater than 80 degrees, greater than 70 degrees, greater than 60 degrees, greater than 45 degrees, greater than 25 degrees, between 50 degrees and 70 degrees, etc.

In FIGS. 13 and 15, the off-axis light blocking angular filters are symmetrical. This example is merely illustrative. If desired, the off-axis light blocking angular filters may be asymmetrical. Similarly, in FIGS. 14 and 16, the on-axis light blocking angular filters are symmetrical (and pass two discrete off-axis cones of light). This example is merely illustrative. If desired, the on-axis light blocking angular filters may only pass one off-axis cone of light or may pass two discrete off-axis cones of light having different sizes.

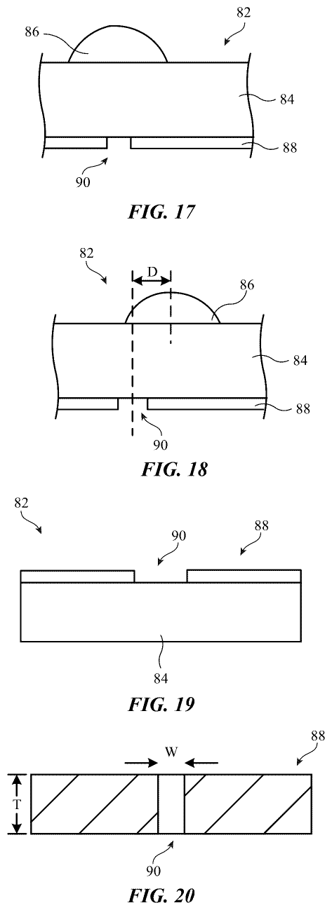

The examples of angular filters shown in FIGS. 13-16 are merely illustrative. In general, the angular filters may be formed using any desired arrangement. In some cases, as shown in the side view of the angular filter 82 in FIG. 17, the angular filter may include a microlens 86 on transparent layer 84. Microlens 86 may overlap an opening 90 in mask 88. This type of angular filter may block off-axis light (similar to the angular filters of FIGS. 13 and 15). A light detecting pixel or light source for the optical touch sensor may be located under opening 90 in alignment with opening 90.

In another possible arrangement, as shown in the side view of the angular filter 82 in FIG. 18, a lateral offset D is included between the center of lens 86 and the center of opening 90. This results in angular filter 82 in FIG. 18 passing only off-axis light of a desired angle while blocking on-axis light (similar to the angular filters of FIGS. 14 and 16).

In the example of FIGS. 13 and 15, two masks are used to define the off-axis light blocking angular filter. This example is merely illustrative. If desired, an off-axis light blocking angular filter may be formed from a single mask with an opening 90, as shown in the side view of the angular filter 82 in FIG. 19.

In general, masks such as mask 88 in FIGS. 13-19 may be formed on any suitable transparent layer(s) 84. FIG. 20 shows how mask 88 may be formed from a through-hole aperture in a relatively thick display layer (e.g., a pixel definition layer or other opaque display layer). In the FIG. 20 configuration, the width W of opening 90 is smaller than the thickness T of the opaque layer forming mask 88. Masks such as the masks 88 of FIGS. 13-20 may be used with or without one or more lenses such as lens 86. The angular light filters formed using lenses 86 and/or masks 88 may each overlap and be aligned with a respective light detector (e.g., a pixel P with a photodetector) or a respective light source (e.g., a pixel P with a light source).

To optimize discrimination between a user's finger and water (such as water droplets), different combinations of angular filters may be used for the light sources and photodetectors in the optical touch sensor.

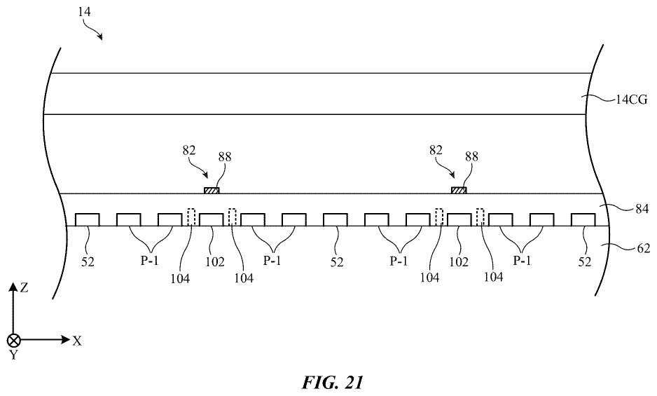

As a first example, shown in FIG. 21, no angular filters may be applied to light sources 52. In contrast, angular filters 82 that block on-axis light while passing off-axis light may be formed over photodetectors 102. As shown in FIG. 21, photodetectors 102, light sources 52, and image pixels P-1 that are used in presenting images for a user of device 10 (e.g., an array of red, green, and blue light-emitting diodes) are all mounted on a common substrate 62. Substrate 62 may be a flexible or rigid layer of polymer forming a flexible or rigid printed circuit or may be formed from other substrate materials. Photodetectors 102, light sources 52, and/or image pixels P-1 may all optionally be formed from surface mount technology (SMT) components that are coupled (e.g., soldered, adhered, etc.) to substrate 62. Photodetectors 102, light sources 52, and/or image pixels P-1 may all optionally be formed crystalline semiconductor dies.

In FIG. 21, no angular filters are formed over light sources 52. Light sources 52 may have an inherent distribution of intensity of emitted light across viewing angles. For example, light sources 52 may emit light with a Lambertian distribution having a peak brightness at an on-axis angle parallel to the surface normal of display cover layer 14CG and decreasing brightness at increasing angles from the surface normal of display cover layer 14CG. However, no angular filters are included to disrupt or change the inherent emission profile of light sources 52.

In contrast, each photodetector 102 may have a corresponding angular filter 82. Each photodetector 102 may be physically aligned with and overlapped by its respective angular filter. In FIG. 21, angular filters 82 for the photodetectors are on-axis light blocking angular filters that block on-axis light while passing off-axis light (similar to as shown in FIG. 14). As a specific example, angular filters 82 may pass light at angles between −90 degrees and −60 degrees and between 60 degrees and 90 degrees. In other words, angle X (as discussed in connection with FIG. 14) is equal to 60 degrees. This example is merely illustrative and angle X for FIG. 21 may instead be less than 80 degrees, less than 70 degrees, less than 60 degrees, less than 45 degrees, less than 25 degrees, greater than 80 degrees, greater than 70 degrees, greater than 60 degrees, greater than 45 degrees, greater than 25 degrees, between 50 degrees and 70 degrees, etc.

In general, each angular filter for a photodetector in the optical touch sensor 14 may have the same filtering profile. Alternatively, different photodetectors may be covered by angular filters having differing filtering profiles.

FIG. 21 also shows how each photodetector may optionally be surrounded by light-blocking sidewalls 104. Light-blocking sidewalls may partially or completely surround a given photodetector 102 in the lateral direction (e.g., within the XY-plane). The light-blocking sidewalls may prevent undesired crosstalk from adjacent image pixels P-1 and/or light sources 52. The light-blocking sidewalls may be formed from a reflective or light absorbing material. The light-blocking sidewalls may have a transmission that is less than 25%, less than 15%, less than 5%, less than 2%, etc. In general, light-blocking sidewalls may be included around one or more photodetectors 102 in any of the optical touch sensor arrangements shown and described herein.

In FIG. 21, masking layers 88 for the angular filters 82 are formed on a shared transparent layer 84. Transparent layer 84 may be an encapsulant layer that conforms to light sources 52, photodetectors 102, and image pixels P-1. This example is merely illustrative. In general, transparent layer 84 may be any desired layer in the electronic device. Additionally, the example in FIG. 21 of multiple angular filters sharing transparent layer 84 is merely illustrative. In another possible arrangement, each angular filter may include a discrete transparent layer that supports one or more masking layers.

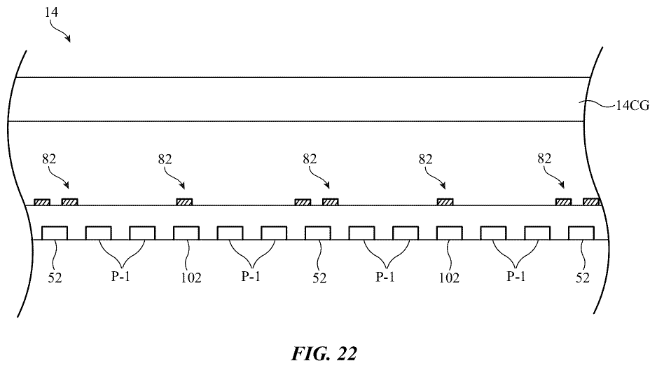

In another possible arrangement, shown in FIG. 22, angular filters are formed over both light sources 52 and photodetectors 102. Similar to as in FIG. 21, each photodetector 102 may have a corresponding angular filter 82. Each photodetector 102 may be physically aligned with and overlapped by its respective angular filter. In FIG. 22, angular filters 82 for the photodetectors are on-axis light blocking angular filters that block on-axis light while passing off-axis light (similar to as in FIGS. 14 and 21). As a specific example, angular filters 82 may pass light at angles between −90 degrees and −60 degrees and between 60 degrees and 90 degrees. In other words, angle X (as discussed in connection with FIG. 14) is equal to 60 degrees. This example is merely illustrative and angle X for FIG. 22 may instead be less than 80 degrees, less than 70 degrees, less than 60 degrees, less than 45 degrees, less than 25 degrees, greater than 80 degrees, greater than 70 degrees, greater than 60 degrees, greater than 45 degrees, greater than 25 degrees, between 50 degrees and 70 degrees, etc.

In FIG. 22, each light source 52 may also have a corresponding angular filter 82. Each light source 52 may be physically aligned with and overlapped by its respective angular filter. In FIG. 22, angular filters 82 for the light sources are off-axis light blocking angular filters that block off-axis light while passing on-axis light (similar to as in FIG. 15). As a specific example, angular filters 82 may pass light at angles between −15 degrees and 15 degrees. In other words, angle X (as discussed in connection with FIG. 15) is equal to 15 degrees. This example is merely illustrative and angle X for FIG. 22 may instead be less than 45 degrees, less than 30 degrees, less than 20 degrees, less than 15 degrees, less than 10 degrees, less than 5 degrees, greater than 45 degrees, greater than 30 degrees, greater than 20 degrees, greater than 15 degrees, greater than 10 degrees, greater than 5 degrees, between 5 degrees and 20 degrees, between 5 degrees and 15 degrees, between 10 degrees and 20 degrees, etc.

In general, each angular filter for a light source in the optical touch sensor 14 may have the same filtering profile. Alternatively, different light sources may be covered by angular filters having differing filtering profiles.

In FIG. 22, masking layers 88 for the angular filters 82 for both the light sources and the photodetectors are formed on a shared transparent layer 84. This example is merely illustrative. In another possible arrangement, each angular filter may include a discrete transparent layer that supports one or more masking layers. In yet another possible arrangement, the angular filters for the light sources may share a first (optionally patterned) transparent layer and the angular filters for the photodetectors may share a second, different (optionally patterned) transparent layer.

With the arrangements of FIGS. 21 and 22, discrimination between a user's finger and water droplets may be achieved using image intensity thresholding. In other words, a detected signal by a photodetector above a given threshold indicates the presence of user's finger. Using only image intensity thresholding in this manner results in simple processing requirements to operate the optical touch sensor.

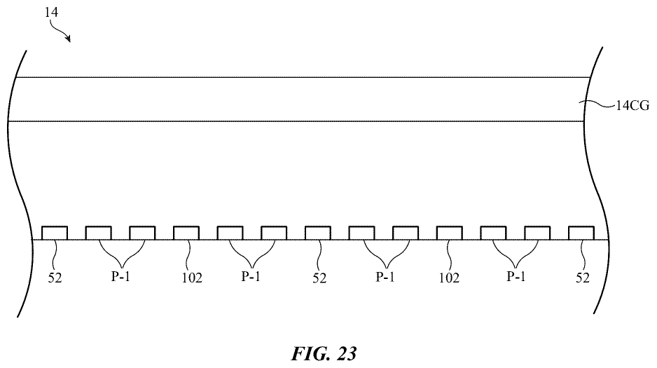

Some optical touch sensors may not be able to discriminate between a user's finger and water droplets using image intensity thresholding alone. In these cases, pattern recognition algorithms may sometimes be used to consistently discriminate between a user's finger and water droplets. FIGS. 23-25 are side views of illustrative displays with optical touch sensors that may rely on pattern recognition to discriminate between a user's finger and water droplets. With these optical touch sensors, water droplets may produce a distinct pattern (with two distinct peaks at opposing edges of the water droplets) in the signals detected by the photodetectors. The pattern recognition algorithm may recognize this distinct pattern and identify the item creating the signal as a water droplet (as opposed to a user's finger).

In FIG. 23, no angular filters are formed over light sources 52. Light sources 52 may have an inherent distribution of intensity of emitted light across viewing angles. For example, light sources 52 may emit light with a Lambertian distribution having a peak brightness at an on-axis angle parallel to the surface normal of display cover layer 14CG and decreasing brightness at increasing angles from the surface normal of display cover layer 14CG. No angular filters are included to disrupt or change the inherent emission profile of light sources 52.

Similarly, no angular filters are formed over photodetectors 102 in FIG. 23. Photodetectors 102 may have an inherent sensitivity to light at various incident angles. However, no angular filters are included to disrupt or change the inherent sensitivity profile of photodetectors 102.

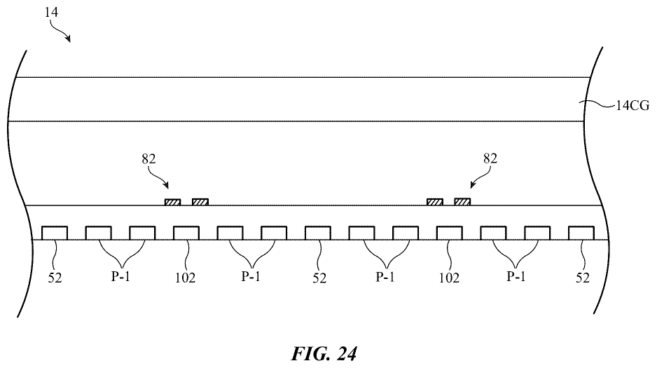

In FIG. 24, no angular filters are formed over light sources 52 (as discussed in connection with FIGS. 21 and 23 above). Each photodetector 102 may have a corresponding angular filter 82. Each photodetector 102 may be physically aligned with and overlapped by its respective angular filter. In FIG. 24, angular filters 82 for the photodetectors are off-axis light blocking angular filters that block off-axis light while passing on-axis light (similar to as in FIG. 13). As a specific example, angular filters 82 may pass light at angles between −10 degrees and 10 degrees. In other words, angle X (as discussed in connection with FIG. 13) is equal to 10 degrees. This example is merely illustrative and angle X for FIG. 24 may instead be less than 45 degrees, less than 30 degrees, less than 20 degrees, less than 15 degrees, less than 10 degrees, less than 5 degrees, greater than 45 degrees, greater than 30 degrees, greater than 20 degrees, greater than 15 degrees, greater than 10 degrees, greater than 5 degrees, between 5 degrees and 20 degrees, between 5 degrees and 15 degrees, between 10 degrees and 20 degrees, etc.

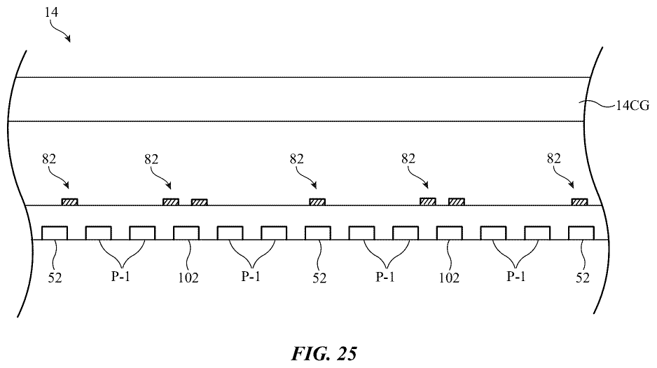

In another possible arrangement, shown in FIG. 25, angular filters are formed over both light sources 52 and photodetectors 102. Similar to as in FIG. 24, each photodetector 102 may have a corresponding angular filter 82 that passes on-axis light while blocking off-axis light. Each photodetector 102 may be physically aligned with and overlapped by its respective angular filter. As a specific example, angular filters 82 for photodetectors 102 in FIG. 25 may pass light at angles between −10 degrees and 10 degrees. In other words, angle X (as discussed in connection with FIG. 13) is equal to 10 degrees. This example is merely illustrative and angle X for FIG. 25 (for the angular filters over the photodetectors) may instead be less than 45 degrees, less than 30 degrees, less than 20 degrees, less than 15 degrees, less than 10 degrees, less than 5 degrees, greater than 45 degrees, greater than 30 degrees, greater than 20 degrees, greater than 15 degrees, greater than 10 degrees, greater than 5 degrees, between 5 degrees and 20 degrees, between 5 degrees and 15 degrees, between 10 degrees and 20 degrees, etc.

In FIG. 25, each light source 52 may also have a corresponding angular filter 82. Each light source 52 may be physically aligned with and overlapped by its respective angular filter. In FIG. 25, angular filters 82 for the light sources are on-axis light blocking angular filters that block on-axis light while passing off-axis light. As a specific example, angular filters 82 (for light sources 52 in FIG. 25) may pass light at angles between −90 degrees and −40 degrees and between 40 degrees and 90 degrees. In other words, angle X (as discussed in connection with FIG. 16) is equal to 40 degrees. This example is merely illustrative and angle X for FIG. 25 may instead be less than 80 degrees, less than 70 degrees, less than 60 degrees, less than 45 degrees, less than 25 degrees, greater than 80 degrees, greater than 70 degrees, greater than 60 degrees, greater than 45 degrees, greater than 25 degrees, between 30 degrees and 50 degrees, between 50 degrees and 70 degrees, etc.

In connection with FIG. 9, an example was shown where an index-matching layer 78 is included between light source 52 and display cover layer 14CG. In the arrangements of FIGS. 21-25 (where multiple light sources 52 are positioned below display cover layer 14CG), each light source may have a corresponding index-matching layer 78, a single index-matching layer 78 may be used for all of the light sources, or the index-matching layer may be omitted for one or more of the light sources.

It should be noted that the optical touch sensors of FIGS. 21-25 may detect light through direct illumination of a user's finger and/or through frustration of total internal reflection by the user's finger.

Ultimately, the arrangements for the light sources and the photodetectors in FIGS. 21-25 (with various angular filter arrangements) have a sufficiently high signal-to-noise ratio between light reflected off of a user's finger (which is desirable to sense/detect) and light reflected off of water (which is desirable to not sense/detect) to discriminate between the user's finger and water. By maximizing the detection of light from the user's finger and minimizing the detection of light from water, the optical touch sensors of FIGS. 21-25 accurately sense finger touches without improperly registering water (e.g., full immersion of device 10 in water) or water droplets on display cover layer 14CG as finger touches. The optical touch sensors of FIGS. 21-25 therefore maintain proper functionality even when the device (e.g., cover layer 14CG) is immersed in water. The angular filters in the optical touch sensors herein block more reflections from water than reflections from the user's finger. Therefore, the angular filters improve the discrimination of the optical touch sensor between the user's finger and water.

In addition to improving the discrimination of the optical touch sensor between the user's finger and water, the angular filters may improve the discrimination of the optical touch sensor between the user's finger touching the display and hovering over the display. It may be desirable for the optical touch sensor to only register touch when the user's input directly contacts display cover layer 14CG. The user's finger may sometimes hover over display cover layer 14CG without touching display cover layer 14CG (e.g., the user's finger may be separated from the display cover layer by a gap of 1 millimeter or less, 0.1 millimeter or less, 0.01 millimeter or less, etc.). Applying angular filters to the light sources and/or photodetectors of the optical touch sensor (e.g., as in any of FIG. 21, FIG. 22, FIG. 24, and FIG. 25) may improve the discrimination of the optical touch sensor between the user's finger touching the display and hovering over the display. The optical touch sensors depicted in FIG. 21, FIG. 22, FIG. 24, and FIG. 25 may (desirably) not detect a finger hover as a touch input.

Including angular filters in the optical touch sensors may also improve rejection of ambient light within the optical touch sensor. Without angular filters, ambient light may be detected by the photodetectors in the optical touch sensor, which may reduce the signal-to-noise ratio in bright ambient light conditions. Including an angular filter over the photodetector that blocks on-axis light (e.g., as in FIGS. 21 and 22) may block the ambient light and maintain high signal-to-noise ratio even in bright ambient light.

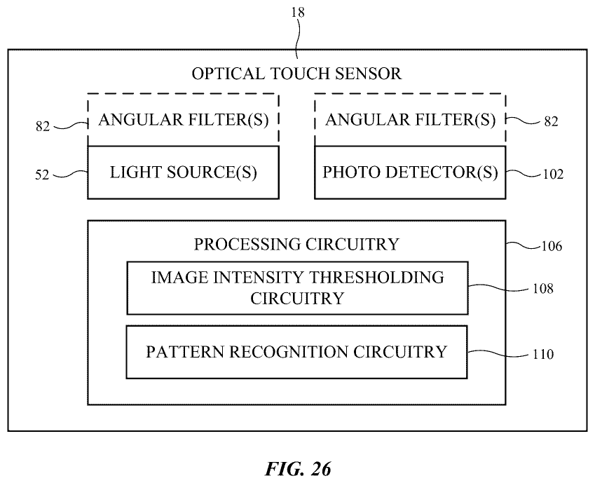

FIG. 26 is a schematic diagram of an optical touch sensor of the type shown and discussed herein. As shown, the optical touch sensor may include one or more light sources 52 and one or more photodetectors 102 (sometimes referred to as light detectors 102). The light sources 52 may emit infrared and/or visible light. Photodetectors 102 may detect reflections of the light emitted by the light sources (e.g., infrared and/or visible light). Angular filters 82 may optionally be formed on one or both of the light sources and the photodetectors. Including angular filters may improve discrimination between a user's finger and water in the optical touch sensor, may improve discrimination between touch and hover events, and may improve ambient light rejection in the optical touch sensor. The angular filters may be on-axis light blocking angular filters and/or off-axis light blocking angular filters.

As shown in FIG. 26, optical touch sensor 18 also includes processing circuitry 106. Processing circuitry 106 may process data from photodetectors 102 to determine if (and where in the XY-plane) a user's finger touches display cover layer 14CG. Processing circuitry 106 may include image intensity thresholding circuitry 108 to identify touches by a user's finger. The image intensity thresholding circuitry 108 may compare real-time signals from the photodetectors to one or more thresholds to determine if a user's finger is present over each photodetector. In some cases, the processing performed by image intensity thresholding circuitry 108 alone is sufficient to identify touches from a user's finger without falsely identifying water droplets as user touches. For example, in the arrangements of FIGS. 21 and 22, image intensity thresholding circuitry 108 is sufficient to accurately discriminate between a user's finger and water droplets. In other cases, processing circuitry 106 may additionally include pattern recognition circuitry 110 to identify touches from a user's finger without falsely identifying water droplets as user touches. The pattern recognition circuitry 110 may have stored data regarding patterns that are caused by water droplets but not a user's finger. The pattern recognition circuitry may analyze real-time data from photodetectors 102 to determine if reflections measured by the photodetectors are caused by a user's finger or water droplets. Specifically, water droplets may cause a characteristic signal profile with two discrete peaks. The pattern recognition circuitry may determine that a water droplet (and not a user's finger) is present when this type of profile is detected.

Processing circuitry 106 (and corresponding circuitry 108 and circuitry 110) may sometimes be considered a part of control circuitry 16 in FIG. 1. Processing circuitry 106 (and corresponding circuitry 108 and circuitry 110) may include one or more microprocessors, microcontrollers, digital signal processors, power management units, application specific integrated circuits, etc.

The foregoing is merely illustrative and various modifications can be made to the described embodiments. The foregoing embodiments may be implemented individually or in any combination.

What is claimed is:

1. An electronic device configured to gather touch input from a finger, comprising:
a display having a display cover layer with a surface, wherein the surface has a surface normal; and
an optical touch sensor configured to distinguish between when the surface is contacted by the finger and when the surface is contacted by a water droplet, the optical touch sensor comprising:
light sources configured to emit light into the display cover layer;
light detectors that are configured to detect reflections of the light when the surface is contacted by the finger; and
angular filters, wherein each angular filter blocks light at a first subset of incident angles from reaching a respective light detector of the light detectors and passes light at a second subset of incident angles to the respective light detector and wherein the first subset of incident angles includes light that is parallel to the surface normal.

2. The electronic device defined in claim 1, wherein the display has an array of light-emitting diodes configured to display an image.

3. The electronic device defined in claim 2, wherein the light sources, the light detectors, and the array of light-emitting diodes are coplanar.

4. The electronic device defined in claim 2, further comprising:
a substrate, wherein the light sources, the light detectors, and the array of light-emitting diodes are mounted on the substrate.

5. The electronic device defined in claim 2, wherein the array of light-emitting diodes comprises an array of crystalline semiconductor light-emitting diode dies.

6. The electronic device defined in claim 1, wherein the second subset of incident angles includes angles relative to the surface normal between −90 degrees and a negative angle having a given magnitude, wherein the second subset of incident angles includes angles relative to the surface normal between a positive angle having the given magnitude and 90 degrees, and wherein the given magnitude is between 50 degrees and 70 degrees.

7. The electronic device defined in claim 1, wherein the second subset of incident angles includes angles relative to the surface normal between −90 degrees and −60 degrees and wherein the second subset of incident angles includes angles relative to the surface normal between 60 degrees and 90 degrees.

8. The electronic device defined in claim 1, further comprising:
additional angular filters, wherein each additional angular filter overlaps a respective light source of the light sources in a direction parallel to the surface normal.

9. The electronic device defined in claim 8, wherein each additional angular filter blocks light at a third subset of incident angles from a respective light source of the light sources and passes light at a fourth subset of incident angles from the respective light source and wherein the fourth subset of incident angles includes light that is parallel to the surface normal.

10. The electronic device defined in claim 9, wherein the fourth subset of incident angles includes angles relative to the surface normal between a negative angle having a given magnitude and a positive angle having the given magnitude and wherein the given magnitude is between 5 degrees and 20 degrees.

11. The electronic device defined in claim 9, wherein the fourth subset of incident angles includes angles relative to the surface normal between −15 degrees and 15 degrees.

12. The electronic device defined in claim 1, wherein the light detectors are configured to detect the reflections of the light when the surface is contacted by the finger and while the display cover layer is immersed in water.

13. The electronic device defined in claim 1, wherein the optical touch sensor is configured to distinguish between when the surface is contacted by the finger and when the finger hovers over the surface.

14. An electronic device configured to gather touch input from a finger, comprising:
a display having a display cover layer with a surface, wherein the surface has a surface normal; and
an optical touch sensor configured to distinguish between when the surface is contacted by the finger and when the surface is contacted by a water droplet, the optical touch sensor comprising:
light sources configured to emit light into the display cover layer;
light detectors that are configured to detect reflections of the light when the surface is contacted by the finger; and
angular filters, wherein each angular filter blocks light at a first subset of incident angles from a respective light source of the light sources and passes light at a second subset of incident angles from the respective light source.

15. The electronic device defined in claim 14, wherein the first subset of incident angles includes light that is parallel to the surface normal.

16. The electronic device defined in claim 15, wherein the second subset of incident angles includes angles relative to the surface normal between −90 degrees and a negative angle having a given magnitude, wherein the second subset of incident angles includes angles relative to the surface normal between a positive angle having the given magnitude and 90 degrees, and wherein the given magnitude is between 30 degrees and 50 degrees.

17. The electronic device defined in claim 15, wherein the second subset of incident angles includes angles relative to the surface normal between −90 degrees and-40 degrees and wherein the second subset of incident angles includes angles relative to the surface normal between 40 degrees and 90 degrees.

18. The electronic device defined in claim 14, wherein the second subset of incident angles includes light that is parallel to the surface normal.

19. The electronic device defined in claim 18, wherein the second subset of incident angles includes angles relative to the surface normal between a negative angle having a given magnitude and a positive angle having the given magnitude and wherein the given magnitude is between 5 degrees and 20 degrees.

20. The electronic device defined in claim 18, wherein the second subset of incident angles includes angles relative to the surface normal between −10 degrees and 10 degrees.

21. The electronic device defined in claim 14, wherein the light detectors are configured to detect the reflections of the light when the surface is contacted by the finger and while the display cover layer is immersed in water.

22. An electronic device configured to gather touch input from a finger, comprising:
a display having a display cover layer with a surface, wherein the surface has a surface normal; and
an optical touch sensor configured to distinguish between when the surface is contacted by the finger and when the surface is contacted by a water droplet, the optical touch sensor comprising:
light sources configured to emit light into the display cover layer;
light detectors that are configured to detect reflections of the light when the surface is contacted by the finger;
first angular filters, wherein each first angular filter overlaps a respective light source of the light sources in a direction parallel to the surface normal; and
second angular filters, wherein each second angular filter overlaps a respective light detector of the light detectors in the direction parallel to the surface normal.

23. The electronic device defined in claim 22, wherein each first angular filter passes light that is parallel to the surface normal and wherein each second angular filter blocks light that is parallel to the surface normal.

24. The electronic device defined in claim 22, wherein the light detectors are configured to detect the reflections of the light when the surface is contacted by the finger and while the display cover layer is immersed in water.
